(19) United States
(12) Patent Application Publication
(10) Pub. No.: US 2024/0421746 A1
(43) Pub. Date: Dec. 19, 2024

(54) MOTOR CONTROL DEVICE AND SEMICONDUCTOR UNIT

(71) Applicant: Mitsubishi Electric Corporation, Tokyo (JP)

(72) Inventors: Noboru MIYAMOTO, Tokyo (JP); Kazuaki HIYAMA, Tokyo (JP)

(73) Assignee: Mitsubishi Electric Corporation, Tokyo (JP)

(21) Appl. No.: 18/700,126

(22) PCT Filed: Jan. 14, 2022
(86) PCT No.: PCT/JP2022/001082

§ 371 Date: Apr. 10, 2024

(51) Int. Cl. H02P 29/60; B60K 1/02; H01L 23/58; H01M 10/42; H02P 27/06

(52) U.S. Cl. CPC H02P 29/60; B60K 1/02; H01L 23/58; H01M 10/425; H02P 27/06; H01M 2220/20

(57) ABSTRACT

Provided is a motor control device that prevents a motor from being unable to be driven in the event of a failure of a battery or an inverter that controls a motor current. A motor control device includes a plurality of semiconductor units each including a semiconductor device (an inverter circuit) driving a motor and a battery providing DC power to the semiconductor device (inverter circuit), wherein semiconductor devices (inverter circuits) of the respective semiconductor units are electrically connected in parallel to the motor.

### TECHNICAL FIELD

The present disclosure relates to motor control devices and, in particular, to highly fault tolerant motor control devices.

### BACKGROUND ART

An inverter that drives a motor using a battery as a power supply receives DC power from a battery pack including a plurality of connected battery cells and a battery including a plurality of connected battery packs, converts the DC power into AC power, and provides the AC power to the motor.

In modern electric vehicles and the like driven by batteries, an inverter is used not only to provide a current from a battery to a motor but also to perform control when the battery is charged with a regenerated current from the motor as disclosed in Patent Document 1.

### PRIOR ART DOCUMENTS

### Patent Document

Patent Document 1: Japanese Patent Application Laid-Open No. 11-283678

### SUMMARY

### Problem to be Solved by the Invention

In the event of a failure of an inverter that controls a motor current, charging and discharging of a motor conventionally cannot be controlled. For example, in the event of a failure of an inverter in an electric vehicle referred to as a battery electric vehicle (EV), the vehicle can be unable to travel at all, or, if a regenerative brake is in operation, it can be difficult to apply the brake.

The present disclosure has been conceived to solve problems as described above, and it is an object of the present disclosure to provide a motor control device that prevents a motor from being unable to be driven in the event of a failure of a battery or an inverter that controls a motor current.

### Means to Solve the Problem

A motor control device according to the present disclosure includes a plurality of semiconductor units each including a semiconductor device that drives a motor and a battery that provides DC power to the semiconductor device, wherein semiconductor devices of the respective semiconductor units are electrically connected in parallel to the motor.

### Effects of the Invention

According to the motor control device according to the present disclosure, the semiconductor devices of the respective semiconductor units are electrically connected in parallel to the motor, so that, even in the event of a failure of the battery or the semiconductor device of any of the semiconductor units, the motor can be prevented from being unable to be driven to increase fault tolerance.

### BRIEF DESCRIPTION OF DRAWINGS

FIG. 1 is a diagram illustrating a configuration of a motor control device according to Embodiment 1.

FIG. 2 is a perspective view illustrating a configuration of a battery pack of a semiconductor unit according to Embodiment 2.

FIG. 3 is a perspective view illustrating a configuration of the semiconductor unit according to Embodiment 2.

FIG. 4 is a diagram illustrating an internal configuration of an inverter unit forming the semiconductor unit according to Embodiment 2.

FIG. 5 is a diagram illustrating a configuration of a motor control device according to Embodiment 3.

FIG. 6 is a flowchart showing autonomous control of unit ECUs performed by the motor control device according to Embodiment 3.

FIG. 7 is a perspective view illustrating a general configuration when semiconductor units are mounted on an electric vehicle.

FIG. 8 is a diagram illustrating a configuration of a motor control device according to Embodiment 5.

FIG. 9 is a cross-sectional view illustrating a configuration of a semiconductor unit according to Embodiment 6.

### DESCRIPTION OF EMBODIMENTS

### Embodiment 1

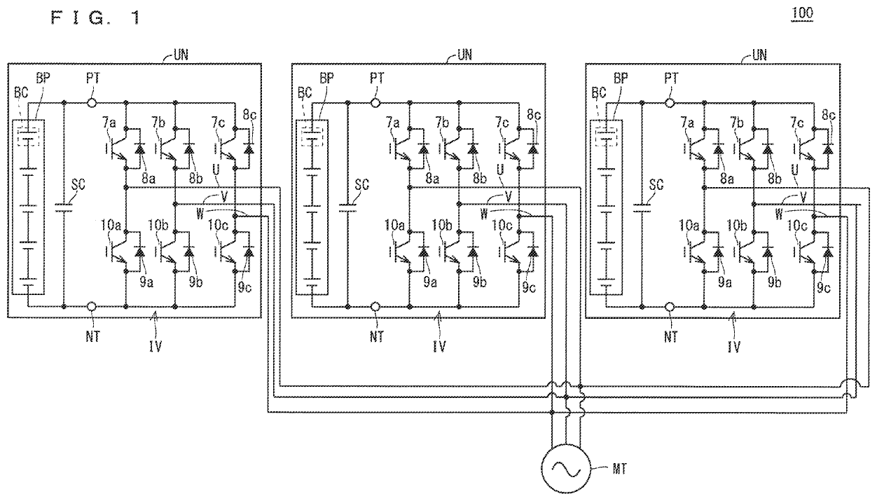

FIG. 1 is a diagram illustrating a configuration of a motor control device 100 according to Embodiment 1. As illustrated in FIG. 1, the motor control device 100 has a configuration in which three semiconductor units UN each including a battery pack BP that includes a plurality of combined battery cells BC and an inverter circuit IV as a semiconductor device that receives DC power from the battery pack BP are included, and the three semiconductor units UN drive a single motor MT. In actuality, a greater number of battery cells BC constitute the battery pack BP, and a plurality of battery packs BP are connected in parallel to constitute a battery, but the battery is illustrated to include a single battery pack BP including five battery cells BC for ease of illustration and description.

In each of the semiconductor units UN, an insulated gate bipolar transistor (IGBT) 7a and an IGBT 10a are connected in series, an IGBT 7b and an IGBT 10b are connected in series, and an IGBT 7c and an IGBT 10c are connected in series between a main power supply line connected to a high-side P terminal PT connected to a positive electrode of the battery pack BP and a main power supply line connected to a low-side N terminal NT connected to a negative electrode of the battery pack BP. A smoothing capacitor SC is connected in parallel to the battery pack BP.

A connection node between the IGBT 7a and the IGBT 10a is a U phase output, a connection node between the IGBT 7b and the IGBT 10b is a V phase output, and a connection node between the IGBT 7c and the IGBT 10c is a W phase output to constitute a three-phase AC inverter.

A diode 8a and a diode 9a are respectively connected in anti-parallel to the IGBT 7a and the IGBT 10a, a diode 8b and a diode 9b are respectively connected in anti-parallel to the IGBT 7b and the IGBT 10b, and a diode 8c and a diode 9c are respectively connected in anti-parallel to the IGBT 7c and the IGBT 10c.

The U phase output, the V phase output, and the W phase output of each of the semiconductor units UN are respectively connected to a U phase input, a V phase input, and a W phase input of the motor MT, so that the three semiconductor units UN are configured to be connected in parallel to the motor MT.

With such a configuration, even in the event of a failure of the battery pack BP or the inverter circuit IV to reduce a function of any of the semiconductor units UN, the motor can be operated without stopping a function of the motor due to complementation with the other semiconductor units UN. Especially in use in an electric vehicle, the function of the motor MT is not stopped, so that the vehicle can be moved to a safe place. While a configuration in which the three semiconductor units UN drive the single motor MT is illustrated in FIG. 1, the above-mentioned effect can be obtained when the number of semiconductor units UN is two or more.

When the three semiconductor units UN drive the single motor MT as illustrated in FIG. 1, if the motor MT has a maximum drive current of 600 A, each inverter circuit IV can have a maximum output current of 200 A. The inverter circuit IV and the battery pack BP can thus be reduced in size, so that each of the semiconductor units UN can be reduced in size.

### Embodiment 2

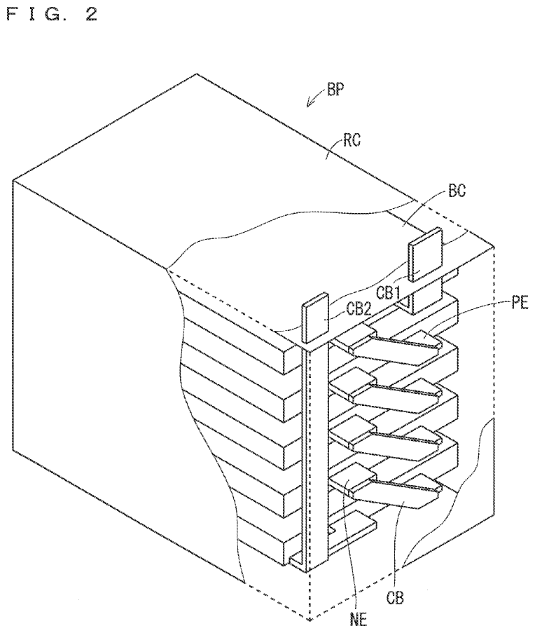

FIG. 2 is a perspective view illustrating a configuration of the battery pack BP of each of the semiconductor units UN of the motor control device 100 illustrated in FIG. 1. As illustrated in FIG. 2, the battery pack BP has a configuration in which a plurality of battery cells BC are stacked, and a positive electrode PE and a negative electrode NE of each of the battery cells BC protrude from one side surface of the cell.

The battery pack BP illustrated in FIG. 2 has a configuration in which the negative electrode NE of an uppermost battery cell BC and the positive electrode PE of a battery cell BC immediately below the uppermost battery cell BC are connected by a connection board CB, the negative electrode NE of an upper battery cell BC and the positive electrode PE of a lower battery cell BC are thereafter connected by a connection board CB, and the uppermost battery cell BC and a lowermost battery cell BC are electrically connected in series. The positive electrode PE of the uppermost battery cell BC and the negative electrode NE of the lowermost battery cell BC are free in FIG. 2, which will be described below.

A stack of the plurality of battery cells BC is housed in a resin case RC and is configured as a single package.

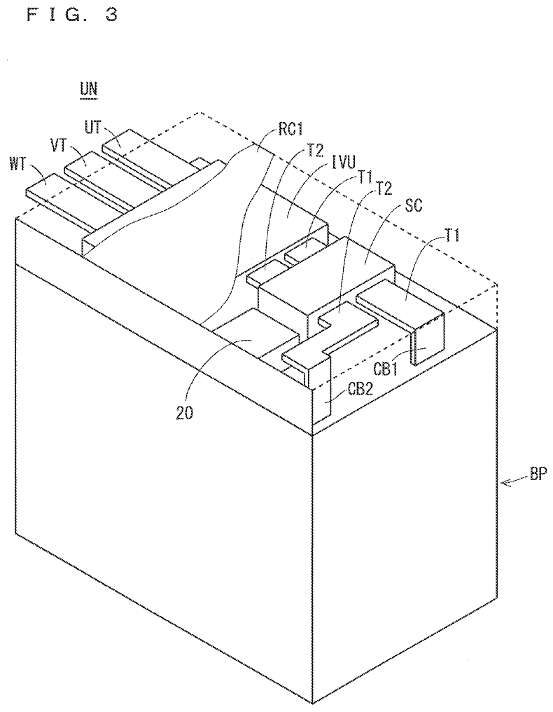

FIG. 3 illustrates a semiconductor unit UN in which an inverter unit IVU, the smoothing capacitor SC, and a unit electronic control unit (ECU) 20 as a control device that controls the inverter unit IVU are mounted on the battery pack BP illustrated in FIG. 2.

As illustrated in FIG. 3, in the semiconductor unit UN, the inverter unit IVU containing the inverter circuit IV, the smoothing capacitor SC, and the unit ECU 20 are mounted on an upper surface of the battery pack BP, and capacitor terminals T1 and T2 protrude from a side surface of the smoothing capacitor SC. The capacitor terminal T1 is connected to the positive electrode PE of the uppermost battery cell BC by a connection board CB1, and the capacitor terminal T2 is connected to the negative electrode NE of the lowermost battery cell BC by a connection board CB2.

The capacitor terminals T1 and T2 also protrude from a side surface of the smoothing capacitor SC on a side of the inverter unit IVU and are respectively connected to the P terminal PT (FIG. 1) and the N terminal NT (FIG. 1) in the inverter unit IVU.

A U phase output terminal UT, a V phase output terminal VT, and a W phase output terminal WT protrude from a side surface of the inverter unit IVU on an opposite side from the smoothing capacitor SC.

The unit ECU 20 includes a control circuit that controls the inverter circuit IV, and the inverter unit IVU, the smoothing capacitor SC, and the unit ECU 20 are housed in a resin case RC1 and are configured as a single package, and are in close contact with the battery pack BP.

An arrangement space can thus be reduced compared with a case where the battery and the inverter circuit are arranged separately. That is to say, in a conventional electric vehicle, when the motor has a maximum drive current of 600 A, for example, a battery having a capacity of 600 A and an inverter circuit having a rated output of 600 A are arranged separately, and, in particular, the inverter circuit is disposed near the motor. A disposition space for the inverter circuit requiring a large volume is thus provided on the top of the motor. A vehicle in which a motor is disposed on an axle has recently been developed, and it becomes difficult to provide the disposition space for the inverter circuit requiring a large volume on the top of the motor. When three semiconductor units UN as illustrated in FIG. 3 are used to drive a single motor, however, arrangement of the three semiconductor units UN on a chassis of the vehicle eliminates the need to provide a large space for the inverter circuit on the top of the motor to reduce the disposition space. This allows for securement of a crash zone at an accident and a space under a hood and securement of a loading space.

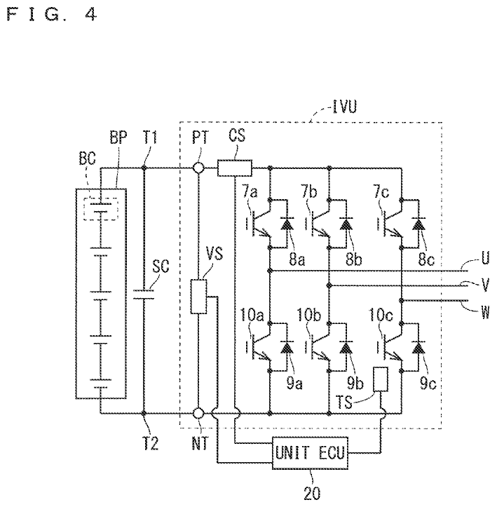

FIG. 4 is a diagram illustrating an internal configuration of the inverter unit IVU illustrated in FIG. 3. As illustrated in FIG. 4, the inverter unit IVU includes a voltage sensor VS connected between the P terminal PT and the N terminal NT, a current sensor CS interposed within the main power supply line connected to the P terminal PT, and a temperature sensor TS provided, for example, near the IGBT 10c.

Detected outputs of the voltage sensor VS, the current sensor CS, and the temperature sensor TS are input into the unit ECU 20.

The voltage sensor VS detects a voltage as an output voltage of the battery pack BP and an input voltage of the inverter circuit IV, and the unit ECU 20 detects a state of charge of the battery pack BP based on the detected voltage and controls a principal current of the inverter circuit IV.

By providing the voltage sensor VS, overcharging of the battery can be prevented using a battery controller provided in the unit ECU 20, which is not illustrated, and uniform consumption of the battery can be achieved through discharging from a cell having a large battery charge using cell controllers provided for the respective battery cells BC. A charging current is preferentially increased for a cell having a small charge at charging, so that a charging time can be reduced. Known technology disclosed, for example, in Japanese Patent Application Laid-Open No. 2000-299939 can be used for control of charging and discharging of the battery pack BP.

By providing the temperature sensor TS, the unit ECU 20 estimates a temperature of the battery pack BP from a difference between a temperature of the IGBTs during operation detected by the temperature sensor TS and a heating value predicted from a power loss of the IGBTs predicted in advance. Based on the estimated temperature, the principal current of the inverter circuit IV can be controlled to perform appropriate control of charging and discharging according to the temperature of the battery. There is no need to provide the temperature sensor for the battery pack BP, so that the battery pack BP can be reduced in size, and manufacturing costs can be reduced.

When the battery pack BP and the inverter unit IVU are in close contact with each other, for example, a change in temperature of the IGBTs can be calculated from a thermal resistance Rth (° C./W) of chips of the IGBTs and a power loss LW (W) of the IGBTs by an expression Rth×LW, and the temperature of the battery pack BP can be shown from a detected temperature T (° C.) of the IGBTs by an expression T-Rth×LW.

Such control of charging and discharging allows for, for each battery pack, prevention of overheating, prevention of overloading at a low temperature and a low charging and discharging capability, suppression of deterioration of the battery pack, and prevention of the stop of the vehicle due to a battery failure in the electric vehicle. While an example in which the temperature of the battery pack BP is estimated from the temperature of the IGBTs during operation has been described above, known technology disclosed, for example, in Japanese Patent Application Laid-Open No. 2000-299939 can be used for control of charging and discharging based on detection of the temperature of the battery pack.

While the temperature sensor TS illustrated in FIG. 4 is shown as a sensor independent of an IGBT, such as a thermistor, a temperature sense diode including a cathode connected to an emitter of the IGBT and an anode connected to a temperature sense terminal can also be used. In this case, the temperature sense terminal is connected to a current detection circuit provided in the unit ECU 20 and calculates the temperature of the IGBTs from a detected current.

### Embodiment 3

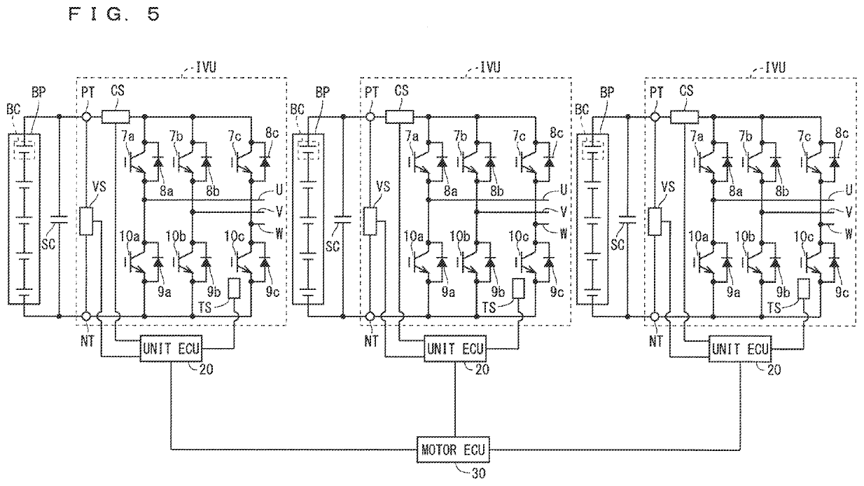

FIG. 5 is a diagram illustrating a configuration in which three inverter units IVU illustrated in FIG. 4 are electrically connected in parallel to a motor (not illustrated), and unit ECUs 20 are each connected to a motor ECU 30 as a higher level control device.

The motor ECU 30 (hereinafter also referred to as the “MCU”) controls an on-off time (a duty) of each switching element to achieve a goal of control of the motor and control of charging and discharging of the battery. That is to say, the MCU inputs the duty and a reference voltage into each of the unit ECUs 20.

The unit ECU 20 into which the duty and the reference voltage have been input compares the voltage of the battery pack BP detected by the voltage sensor VS and the reference voltage and changes, when the actual voltage of the battery pack BP is higher than the reference voltage, the duty so that an on-time is increased to increase the amount of discharge in a case of control in which the duty directs discharging, that is, control to turn on each switching element. In a case of control in which the duty directs charging, the duty is changed so that the on-time is reduced to energize a charging path via diode elements for a long time.

Such control allows for an autonomous change of a control state of each of the inverter circuits IV and allows for, in the event of a failure of any of the semiconductor units UN, handling for each semiconductor unit UN.

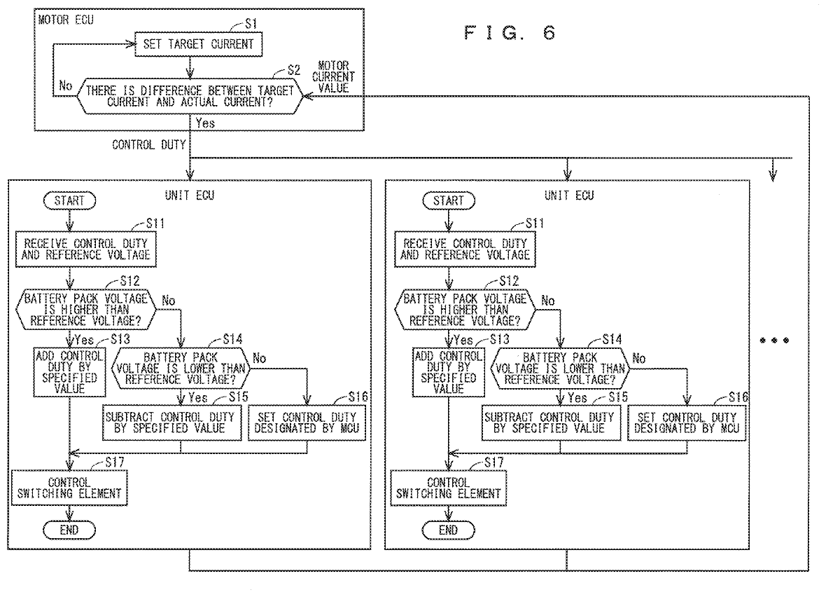

FIG. 6 is a flowchart showing autonomous control of the unit ECUs 20 performed by the motor ECU 30. As shown in FIG. 6, the motor ECU 30 sets a target current input into the motor (step S1) and thereafter continuously checks whether there is a difference between the target current and an actual current fed back from each of the unit ECUs 20 (step S2).

In step S2, when there is the difference between the target current and the actual current (Yes), a control duty to compensate for the difference is output to each of the unit ECUs 20. When the target current and the actual current match, a control duty to designate the target current is output, and processing of setting the target current in step S1 is repeated.

Each of the unit ECUs 20 receives the control duty and the reference voltage from the MCU (step S11), compares the voltage of the battery pack BP and the reference voltage (step S12), and proceeds to step S13 when the voltage of the battery pack BP is higher than the reference voltage (Yes) and proceeds to step S14 when the voltage of the battery pack BP is lower than or equal to the reference voltage (No).

In step S13, the control duty is added by a specified value to increase the on-time to increase the amount of discharge from the battery pack BP, and processing proceeds to step S17. This can prevent an excessive increase in voltage of the battery pack BP.

In step S14, the voltage of the battery pack BP and the reference voltage are compared, and processing transitions to step S15 when the voltage of the battery pack BP is lower than the reference voltage (Yes) and transitions to step S16 when the voltage of the battery pack BP is equal to the reference voltage (No).

In step S15, the control duty is subtracted by a specified value to reduce the on-time to reduce the amount of discharge from the battery pack BP, and processing proceeds to step S17.

In step S16, the control duty designated by the MCU is set, and processing proceeds to step S17.

In step S17, the control duty is provided to each switching element of the inverter circuit IV for control.

As a result of a change of the control duty made by the unit ECU 20, the actual current flowing through the motor is to approach the target current, and control of charging and discharging of the battery is to appropriately be performed. The actual current flowing through the motor is detected by an unillustrated current sensor and is fed back to the motor ECU 30.

While the above-mentioned control flow has been shown as a control flow based on the voltage of the battery pack BP detected by the voltage sensor VS, similar control can be performed using an estimated value of the temperature of the battery pack BP based on the temperature of the switching elements, that is, the IGBTs detected by the temperature sensor TS.

While an example in which the control duty of the switching element is changed has been shown in the above-mentioned control flow, a method of changing a drive frequency of the switching element, that is, a switching speed to increase and reduce the power loss of the switching element can also be used. That is to say, the power loss of the switching element is reduced by reducing the drive frequency and is increased by increasing the drive frequency. Instead of increasing the on-time of the switching element, the drive frequency of the switching element is increased to increase the power loss to perform control to increase the amount of discharge from the battery pack BP. This can prevent an excessive increase in voltage of the battery pack BP.

When the battery pack BP and the inverter unit IVU share a cooling mechanism, control to switch a cooling capability of the cooling mechanism, for example, a flow path of a coolant or a flow speed of the coolant can be performed based on the temperature of the IGBTs and an estimated value of the temperature of the battery pack BP based on the temperature.

### Embodiment 4

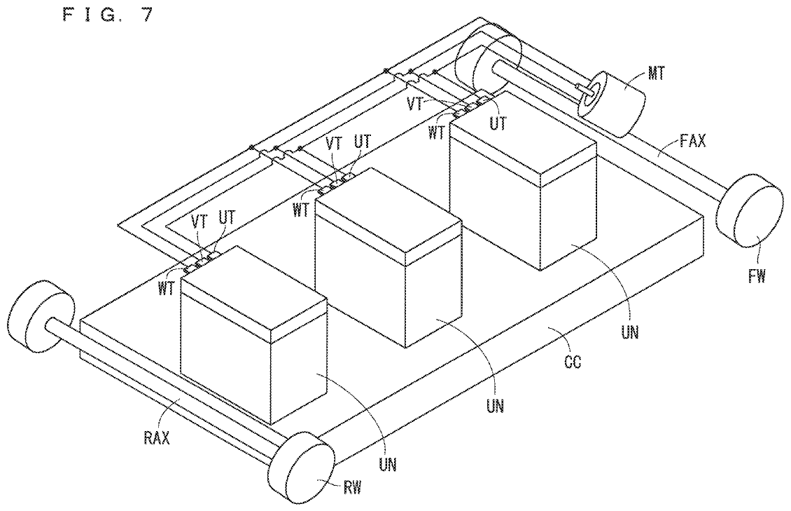

FIG. 7 is a perspective view illustrating a general configuration when the semiconductor units UN illustrated in FIG. 3 are mounted on the electric vehicle, and three semiconductor units UN are mounted on a chassis CC, and a U phase wire UL, a V phase wire VL, and a W phase wire WL from each of the three semiconductor units UN are connected to the motor MT mounted on an axle FAX of front wheels FW.

As described above, mounting the three semiconductor units UN on the chassis CC eliminates the need to provide the disposition space for the inverter circuit requiring a large volume on the top of the motor MT. This allows for securement of the crash zone at the accident and the space under the hood and securement of the loading space.

While an example in which the motor MT is mounted on the axle FAX of the front wheels FW has been illustrated in FIG. 7, the motor MT can be mounted on an axle RAX of rear wheels RW and can be mounted on both the axle FAX of the front wheels FW and the axle RAX of the rear wheels RW. This allows for handling of a rear-wheel drive vehicle and a four-wheel drive vehicle. The motor may be an in-wheel motor contained in a wheel. In this case, the crash zone at the accident, the space under the hood, and the loading space can further be increased.

### Embodiment 5

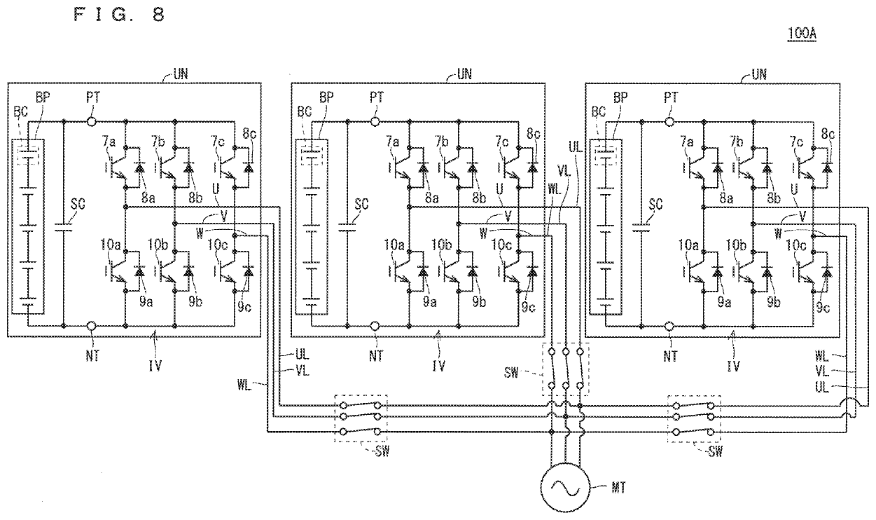

FIG. 8 is a diagram illustrating a configuration of a motor control device 100A according to Embodiment 5. In FIG. 8, the same components as those of the motor control device 100A described with reference to FIG. 1 bear the same reference signs as those of the same components, and redundant description thereof will be omitted.

As illustrated in FIG. 8, the motor control device 100A has a configuration in which relay switches SW are interposed within the U phase wire UL, the V phase wire VL, and the W phase wire WL respectively connecting the U phase output of the semiconductor unit UN and the U phase input of the motor MT, the V phase output of the semiconductor unit UN and the V phase input of the motor MT, and the W phase output of the semiconductor unit UN and the W phase input of the motor MT. As the relay switches SW, semiconductor switching elements or mechanical switches can be used.

With such a configuration, in the event of a failure of the battery pack BP or the inverter circuit IV of any of the semiconductor units UN, a relay switch SW leading to the semiconductor unit UN is shut off (opened) to enable the other semiconductor units UN to drive the motor MT to thereby form a highly fault tolerant system.

Even in the event of a failure of any of the semiconductor units UN, the relay switch SW leading to the semiconductor unit UN is sometimes not shut off. That is to say, as described in Embodiment 1, if the motor MT has a maximum drive current of 600 A, each of the inverter circuits IV can have a maximum output current of 200 A. In the event of a failure of any of the inverter circuits IV to allow only an output current of up to 100 A to be output, the semiconductor unit UN including the inverter circuit IV is used as a semiconductor unit UN having an output of 100 A without shutting off the relay switch SW. The vehicle thus cannot travel at a maximum speed, but the speed can be maintained without significant degradation of normal travel. Each of the semiconductor units UN is configured to be capable of outputting a maximum drive voltage of the motor MT, and, even in the event of a failure of two semiconductor units UN, for example, the remaining one semiconductor unit UN can drive the motor MT to cause the vehicle to travel.

The number of semiconductor units UN is not limited to three, at least two semiconductor units UN are sufficient to obtain a fault tolerant system, and three or more semiconductor units UN can further reduce a maximum output current of each of the semiconductor units UN to form a more secure fault tolerant system.

A degree of reduction in output current to shut off the relay switch SW can be set to the motor ECU in advance, and the relay switch SW can be controlled by determination made by the motor ECU.

### Embodiment 6

The semiconductor unit UN illustrated in FIG. 3 has a configuration in which the inverter unit IVU and the smoothing capacitor SC are mounted on the battery pack BP, and the battery pack BP, the inverter unit IVU, and the smoothing capacitor SC are provided separately and united, but the battery, the inverter, and the smoothing capacitor can be provided integrally.

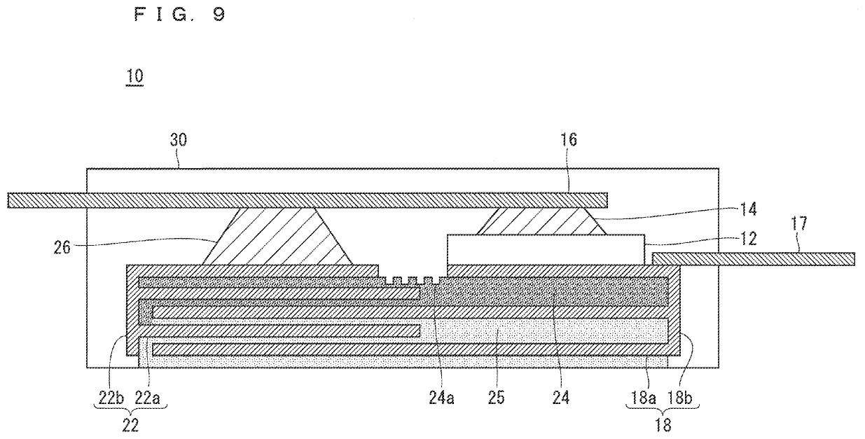

FIG. 9 is a cross-sectional view illustrating a configuration of a semiconductor unit 10 according to Embodiment 6. The semiconductor unit 10 includes a semiconductor device 12. The semiconductor device 12 is an IGBT including an emitter in an upper surface and a collector in a lower surface. A first electrode 16 is electrically connected to the upper surface of the semiconductor device 12 via solder 14. The first electrode 16 functions as an emitter electrode.

A first internal electrode 18 is electrically connected to the lower surface of the semiconductor device 12. The first internal electrode 18 includes a plurality of first comb teeth portions 18a and a first joining portion 18b joining the plurality of first comb teeth portions 18a. Comb teeth portions of the plurality of first comb teeth portions 18a extend in parallel. One comb tooth of the plurality of first comb teeth portions is in surface contact with the lower surface of the semiconductor device 12.

A second electrode 17 is electrically connected to the first internal electrode 18. The second electrode 17 functions as a collector electrode. A second internal electrode 22 is formed at a position opposite the first internal electrode 18. The second internal electrode 22 includes a plurality of second comb teeth portions 22a and a second joining portion 22b joining the plurality of second comb teeth portions 22a. Comb teeth portions of the plurality of second comb teeth portions 22a extend in parallel. The plurality of second comb teeth portions 22a enter gaps between the plurality of first comb teeth portions 18a without contacting the plurality of first comb teeth portions 18a. That is to say, the plurality of first comb teeth portions 18a and the plurality of second comb teeth portions 22a are arranged to mesh with each other without contacting each other.

A dielectric 24 is embedded between one or more upper first comb teeth portions 18a of the plurality of first comb teeth portions 18a and one or more upper second comb teeth portions 22a of the plurality of second comb teeth portions 22a on a side of the semiconductor device 12. The dielectric 24 is formed of ceramics. A capacitor including the dielectric 24, the first comb teeth portions 18a, and the second comb teeth portions 22a and including the first comb teeth portions 18a and the second comb teeth portions 22a as electrodes is thereby formed. The dielectric 24 has a recess 24a.

A solid electrolyte 25 is embedded between one or more lower first comb teeth portions 18a of the plurality of first comb teeth portions 18a and one or more lower second comb teeth portions 22a of the plurality of second comb teeth portions 22a on an opposite side from the semiconductor device 12. The solid electrolyte 25 is formed of oxide ceramics. A battery including the solid electrolyte 25, the first comb teeth portions 18a, and the second comb teeth portions 22a and including the first comb teeth portions 18a and the second comb teeth portions 22a as electrodes is thereby formed.

The second internal electrode 22 is electrically connected to a lower surface of the first electrode 16. Specifically, one comb tooth of the plurality of second comb teeth portions 22a is electrically connected to the lower surface of the first electrode 16 via solder 26. A resin 30 is formed to cover the semiconductor device 12, the first internal electrode 18, and the second internal electrode 22 and externally expose a portion of the first electrode 16, a portion of the second electrode 17, and a portion of the bottom dielectric 24. The resin 30 is formed by transfer molding. The above-mentioned recess 24a is formed in a portion being in contact with the resin 30, so that the recess 24a is filled with the resin 30.

The semiconductor unit 10 illustrated in FIG. 9 has a configuration in which the capacitor is formed on the top of the battery, and the battery and the capacitor are connected in parallel to the semiconductor device 12.

Although not illustrated, the semiconductor device 12 herein has a configuration of the inverter circuit of one phase in which the diode 8a and the diode 9a are respectively connected in anti-parallel to the IGBT 7a and the IGBT 10a connected in series in the inverter circuit IV illustrated in FIG. 1, for example, and the semiconductor unit 10 can have a configuration in which the inverter circuit of one phase, the battery, and the capacitor are connected in parallel.

Connecting three inverter circuits of one phase in parallel results in the inverter circuit IV of three phases illustrated in FIG. 1.

A configuration in which the capacitor is formed integrally on the top of the battery as illustrated in FIG. 9 allows for handling of rapid charging. That is to say, a voltage increases due to a charging current and an internal resistance according to a relationship resistance×current, so that a rapid flow of an overcurrent through a high-resistance portion results in an overvoltage. Thus, at charging, a capacitor having a small internal resistance as a smoothing capacitor is charged first, and the current is allowed to flow though the battery to enable handling of a heavy current.

While the present disclosure has been described in detail, the foregoing description is in all aspects illustrative and not restrictive. It is understood that numerous unillustrated modifications can be devised without departing from the scope of the present disclosure.

Embodiments of the present disclosure can thus freely be combined with each other, and can be modified or omitted as appropriate within the scope of the present disclosure.

1. A motor control device comprising
a plurality of semiconductor units each including a semiconductor device and a battery, the semiconductor device driving a motor, the battery providing DC power to the semiconductor device, wherein
semiconductor devices of the respective semiconductor units are electrically connected in parallel to the motor.

2. The motor control device according to claim 1, wherein
the plurality of semiconductor units each include a control device that controls the semiconductor device,
the semiconductor device and the battery are provided integrally or in close contact with each other,
the semiconductor device is an inverter circuit,
the inverter circuit includes a temperature sensor that measures a temperature of a switching element forming the inverter circuit, and
the control device estimates a temperature of the battery based on the temperature of the switching element measured by the temperature sensor and controls the switching element based on the temperature of the battery.

3. The motor control device according to claim 2, wherein
a thermal resistance of the switching element is multiplied by a power loss of the switching element to calculate a change in temperature of the switching element, and the change in temperature is subtracted from the temperature of the switching element to estimate the temperature of the battery.

4. The motor control device according to claim 1, wherein
the plurality of semiconductor units each include a control device that controls the semiconductor device,
the semiconductor device is an inverter circuit,
the semiconductor device includes a voltage sensor that measures an output voltage of the battery, and
the control device controls a switching element forming the inverter circuit based on the output voltage of the battery measured by the voltage sensor.

5. The motor control device according to claim 4, wherein
the control device compares a reference voltage input from a higher level control device and the output voltage of the battery and controls, when the output voltage of the battery is higher than the reference voltage, the switching element so that the amount of discharge from the battery is increased.

6. The motor control device according to claim 5, wherein
when the output voltage of the battery is higher than the reference voltage, the control device increases an on-time of the switching element to increase the amount of discharge from the battery.

7. The motor control device according to claim 5, wherein
when the output voltage of the battery is higher than the reference voltage, the control device increases a drive frequency of the switching element to increase a power loss to increase the amount of discharge from the battery.

8. The motor control device according to claim 1, wherein
the motor is a motor that causes a vehicle to travel, and
the plurality of semiconductor units are mounted on a chassis of the vehicle.

9. The motor control device according to claim 8, wherein
the motor is mounted on an axle of at least one of a front wheel and a rear wheel of the vehicle or in the front wheel and the rear wheel.

10. The motor control device according to claim 1 further comprising
a switch that individually interrupts electrical connections between semiconductor devices of the respective semiconductor units and the motor.

11. A semiconductor unit comprising:
a semiconductor device; and
a battery that provides DC power to the semiconductor device, wherein
the semiconductor device is mounted on the battery.

12. A semiconductor unit comprising:
a semiconductor device;
a first electrode that is electrically connected to an upper surface of the semiconductor device;
a first internal electrode that includes a plurality of first comb teeth portions and a first joining portion joining the plurality of first comb teeth portions and is electrically connected to a lower surface of the semiconductor device;
a second electrode that is electrically connected to the first internal electrode;
a second internal electrode that includes a plurality of second comb teeth portions and a second joining portion joining the plurality of second comb teeth portions and is electrically connected to a lower surface of the first electrode, the plurality of second comb teeth portions entering gaps between the plurality of first comb teeth portions without contacting the plurality of first comb teeth portions;
a dielectric embedded between an upper first comb teeth portion of the plurality of first comb teeth portions and an upper second comb teeth portion of the plurality of second comb teeth portions on the semiconductor device side; and
a solid electrolyte embedded between a lower first comb teeth portion of the plurality of first comb teeth portions and a lower second comb teeth portion of the plurality of second comb teeth portions on an opposite side from the semiconductor device.
